(19) United States
(12) Patent Application Publication
(10) Pub. No.: US 2007/0229118 A1
(43) Pub. Date: Oct. 4, 2007

(54) Phase Comparator

(75) Inventors: Tatsuya Kobayashi, Tokyo (JP); Hitoyuki Tagami, Tokyo (JP); Katsuhiro Shimizu, Tokyo (JP); Kenkichi Shimomura, Tokyo (JP)

Correspondence Address: BIRCH STEWART KOLASCH & BIRCH, PO BOX 747, FALLS CHURCH, VA, 22040-0747, US

(73) Assignee: Mitsubishi Electric Corporation

(21) Appl. No.: 11/504,694

(22) Filed: Aug. 16, 2006

(30) Foreign Application Priority Data
Mar. 28, 2006 (JP) 2006-089216

(51) Int. Cl. H03D 13/00

(52) U.S. Cl. 327/3

(57) ABSTRACT

A phase comparator includes: first and second detecting units for detecting an amplitude value of a clock signal at falling timing or rising timing of a data signal; an edge comparing unit for identifying as to whether the first detecting unit detects an amplitude value under a rising state or a falling state to output a first identification result, and for identifying as to whether the second detecting unit detects an amplitude value under a rising state or a falling state to output a second identification result; first and second polarity inverting units for inverting a polarity of output of the first and second detecting units; and a signal selecting unit for selecting one of output values of the first and second polarity inverting units in response to a polarity of the data signal to output the selected output value.

### BACKGROUND OF THE INVENTION

1. Field of the Invention

The present invention is related to a phase comparator operable in full bit rates and also in half bit rates.

2. Description of the Related Art

A description is made of a conventional clock data recovery circuit and a conventional phase comparator with reference to FIGS. 6 to 11 (refer to, for instance, “A Si Bipolar Phase and Frequency Detector IC for Clock Extraction up to 8 Gb/s” written by A. Pottbacker et al., IEEE Journal of Solid State Circuits, Vol. SC-27, No. 12, pp 1747-1751, in 1992). FIG. 6 is a block diagram for indicating an arrangement of the conventional clock recovery circuit.

In FIG. 6, the conventional clock data recovery circuit includes a phase comparator 100, a low pass-filter (hereinafter, “LPF”) 200, a voltage controled oscillator (hereinafter, “VCO”) 300, and a data identifier 400.

The phase comparator 100 compares a phase of input data DIN with a phase of a clock CLK1 generated by the VCO 300, and detects a difference between the phases of the two. Then the phase comparator 100 outputs a phase difference signal FEO1 to the LPF 200. The LPF 200 smoothes the phase difference signal FEO1 by removing a higher frequency component from this signal, thereby obtaining a control signal, and outputs the control signal to the VCO 300. The VCO 300 generates the clock CLK1 by adjusting an oscillation frequency based on the control signal, and outputs the generated clock CLK1 to both the phase comparator 100 and the data identifier 400. The data identifier 400 identifies whether the input data DIN is high (“H”) or low (“L”) based on the clock CLK1.

FIG. 7 is a block diagram of the phase comparator 100 shown in FIG. 6. In FIG. 7, the phase comparator 100 includes a first sample-and-hold circuit 110, a second sample-and-hold circuit 120, and a selector 130.

The first sample-and-hold circuit 110 samples an amplitude value of the clock CLK1 during a period when the input data DIN is “H”, and holds the amplitude value of the clock CLK1 at a fall of the input data DIN. The second sample-and-hold circuit 120 samples an amplitude value of the clock CLK1 during a period when the input data DIN is “L”, and holds the amplitude value of the clock CLK1 at a rise of the input data DIN. The selector 130 selects an output SHO2 from the second sample-and-hold circuit 120 when the input data DIN is “H”, and selects an output SHO1 from the first sample-and-hold circuit 110 when the input data DIN is “L”. The selector 130 outputs the selected signal as the phase difference signal FEO1.

Next, operations of the phase comparator 100 will now be explained with reference to a timing chart of FIG. 8. In FIG. 8, the frequency of the clock CLK1 is equal to the bit rate of the input data DIN, and the phase comparator 100 is operated in the full bit rate. Also, the timing chart shown in FIG. 8 represents such a case that the phase of the clock CLK1 is delayed by “Δ” from the phase of the input data DIN.

The input data DIN is entered in this order of “L”, “H”, “L”, “L”, “H”, “L”, “L”, “H”, “L”, “H” and “L” in a non return-to-zero (NRZ) format, namely, in the order of “0”, “1”,“0”, “0”, “1”, “0”, “0”, “1”, “0”,“1”, “1”, and “0” (from right to left).

The first sample-and-hold circuit 110 starts a sampling operation as to the amplitude value of the clock CLK1 when the input data DIN changes from “L” to “H”. The second sample-and-hold circuit 120 holds the amplitude value of the clock CLK1 at the moment when the input data DIN rises. During the period when the input data DIN is “H”, the selector 130 selects the output SHO2 from the second sample-and-hold circuit 120 and outputs it as the phase difference signal FEO1.

When the input data DIN changes from “H” to “L”, the first sample-and-hold circuit 110 holds the amplitude value of the clock CLK1 at the moment when the input data DIN falls. The second sample-and-hold circuit 120 starts a sampling operation as to the amplitude value of the clock CLK1. During the period when the input data DIN is “L”, the selector 130 selects the output SHO1 from the first sample-and-hold circuit 110, and outputs it as the phase difference signal FEO1.

As previously explained, the phase comparator 100 detects the phase difference between the changing points (rising timing and falling timing) of the input data DIN and the rising timing of the clock CLK1 to output a constant DC (Direct Current) signals corresponding to the phase difference. It should be noted that the DC signals outputted from the phase comparator 100 have polarities while the bias level of the clock CLK1 is defined as the reference, and then, delays/leads of phases are detected based upon the polarities. The phase comparator 100 is operated in the full bit rate under normal condition in the above-described manner.

However, as indicated in a timing chart of FIG. 9, there are some possibilities that the phase comparator 100 is operated in a half bit rate in which clock CLK1 frequency is equal to a half of the bit rate of the input data DIN.

Next, operations of the phase comparator 100 will now be explained with reference to a timing chart of FIG. 9. The timing chart shown in FIG. 9 represents such a case that the phase of the clock CLK1 is delayed by “Δ” from the phase of the input data DIN.

The input data DIN is entered in this order of “L”, “H”, “L”, “L”, “H”, “L”, “L”, “H”, “L”, “H” and “L” in the NRZ format, namely, in the order of “0”, “1”, “0”, “0”, “1”, “0”, “0”, “1”, “0”, “1”, and “0” (from right to left).

The operation of the first sample-and-hold circuit 110 and the operation of the second sample-and-hold circuit 120 are identical to those of FIG. 8. The first sample-and-hold circuit 110 holds the amplitude value under the falling state of the clock CLK1, and the second sample-and-hold circuit 120 holds the amplitude value under the rising state of the clock CLK1, so that the polarity of the output SHO1 of the first sample-and-hold circuit 110 and the polarity of the output SHO2 of the second sample-and-hold circuit 120 have an inverting relationship. In order to match the polarity of the output SHO1 of the first sample-and-hold circuit 110 coincident with the polarity of the output SHO2 of the second sample-and-hold circuit 120, for instance, as shown in FIG. 10, even if the polarity inverting circuit 140 is inserted in the output of the first sample-and-hold circuit 110, then such a signal portion surrounded by a dotted line, the polarity of which is inverted, is left in a timing chart of FIG. 11, and thus, the polarities of the output signals of the selector 130 are not matched with each other.

As previously explained, the DC signals outputted from the phase comparator 100 have the polarities. Since the delays and leads of the phases are detected based on the polarities, the polarities of the output signals of the selector 130 must be matched with each other. As previously explained, in the case that the conventional phase comparator 100 is operated in the half bit rate, the signal portions whose polarities are inverted are left in the output signals of the phase comparator 100.

The above-explained conventional sample-and-hold type phase comparator has a problem in that when the conventional sample-and-hold type phase comparator is operated in the half bit rate, the signal portions whose polarities are inverted are left in the output signals of the phase comparator.

### SUMMARY OF THE INVENTION

The present invention has been made to solve the above-mentioned problem, and therefore has an object to provide a phase comparator operable in such a manner that when the phase comparator is operated not only in a full bit rate, but also in a half bit rate, a signal portion whose polarity is inverted is not left in output signals of the phase comparator, namely to provide a phase comparator operable in both the full bit rate and the half bit rate.

A phase comparator according to the present invention includes:

a first detecting means for detecting an amplitude value of a clock signal inputted at falling timing of an inputted data signal;

a second detecting means for detecting an amplitude value of the clock signal at rising timing of the data signal;

an edge comparing means for identifying as to whether the first detecting means detects an amplitude value under a rising state of the clock signal or an amplitude value under a falling state of the clock signal to output a first identification result, and for identifying as to whether the second detecting means detects an amplitude value under a rising state of the clock signal or an amplitude value under a falling state of the clock signal to output a second identification result;

a first polarity inverting means for inverting a polarity of an output of the first detecting means in response to the first identification result derived from the edge comparing means;

a second polarity inverting means for inverting a polarity of an output of the second detecting means in response to the second identification result derived from the edge comparing means; and

a signal selecting means for selecting one of an output value of the first polarity inverting means and an output value of the second polarity inverting means in response to a polarity of the data signal to output the selected output value.

The phase comparator according to the present invention has an effect that when the phase comparator is operated not only in the full bit rate, but also in the half bit rate, the signal portion whose polarity is inverted is not left in the output signals of the phase comparator, namely, such a phase comparator operable in both the full bit rate and the half bit rate can be provided.

### BRIEF DESCRIPTION OF THE DRAWINGS

In the accompanying drawings:

FIG. 1 is a block diagram for representing an arrangement of a phase comparator according to a first embodiment of the present invention;

FIG. 2 is a timing chart for indicating operations of the phase comparator according to the first embodiment of the present invention;

FIG. 3 is a block diagram for representing an arrangement of a phase comparator according to a second embodiment of the present invention;

FIG. 4 is a timing chart for indicating operations of the phase comparator according to the second embodiment of the present invention;

FIG. 5 is a block diagram for representing an arrangement of a phase comparator according to a third embodiment of the present invention;

FIG. 6 is a block diagram for showing the arrangement of a conventional clock data recovery circuit;

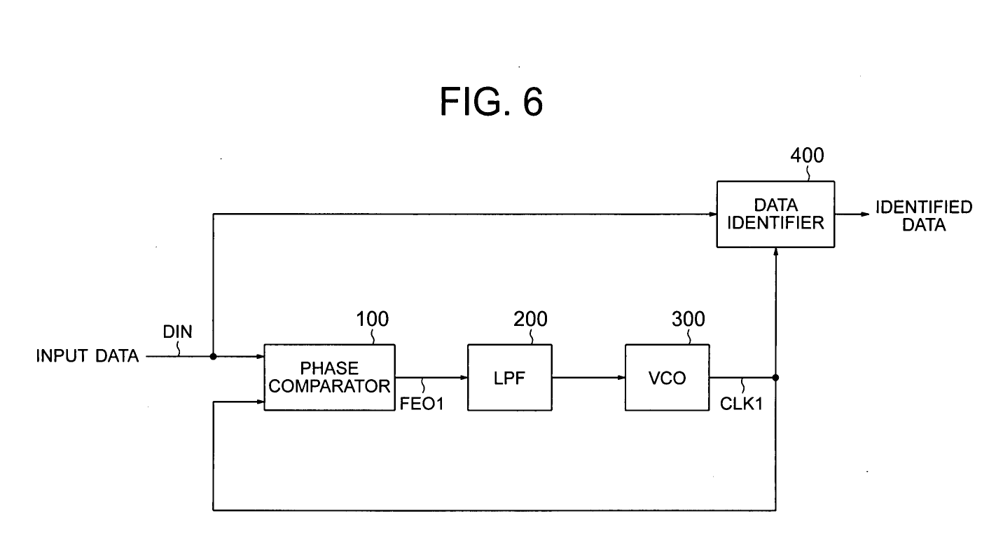

FIG. 7 is a block diagram for indicating the arrangement of the conventional phase comparator shown in FIG. 6;

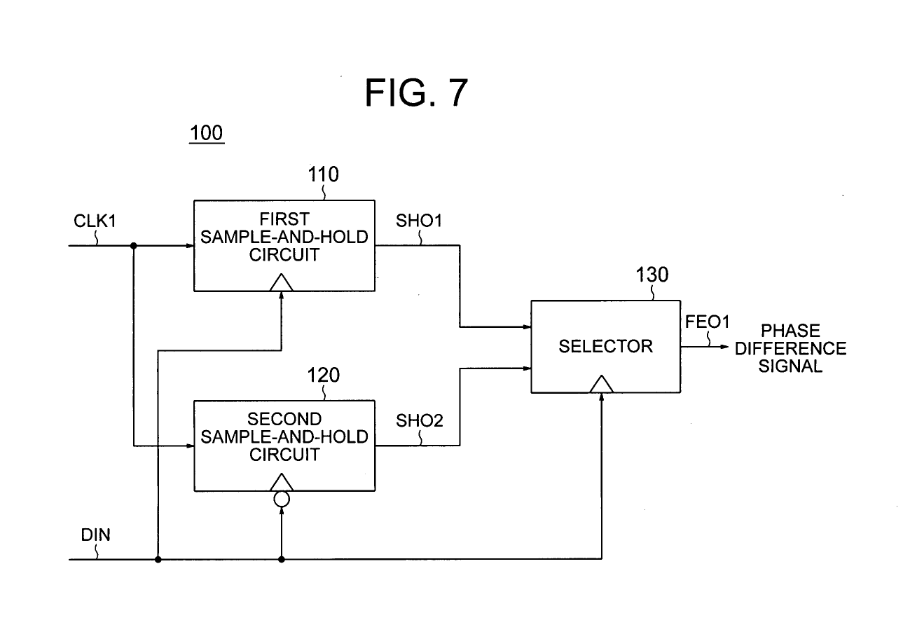

FIG. 8 is a timing chart for indicating operations (full bit rate) of the conventional phase comparator;

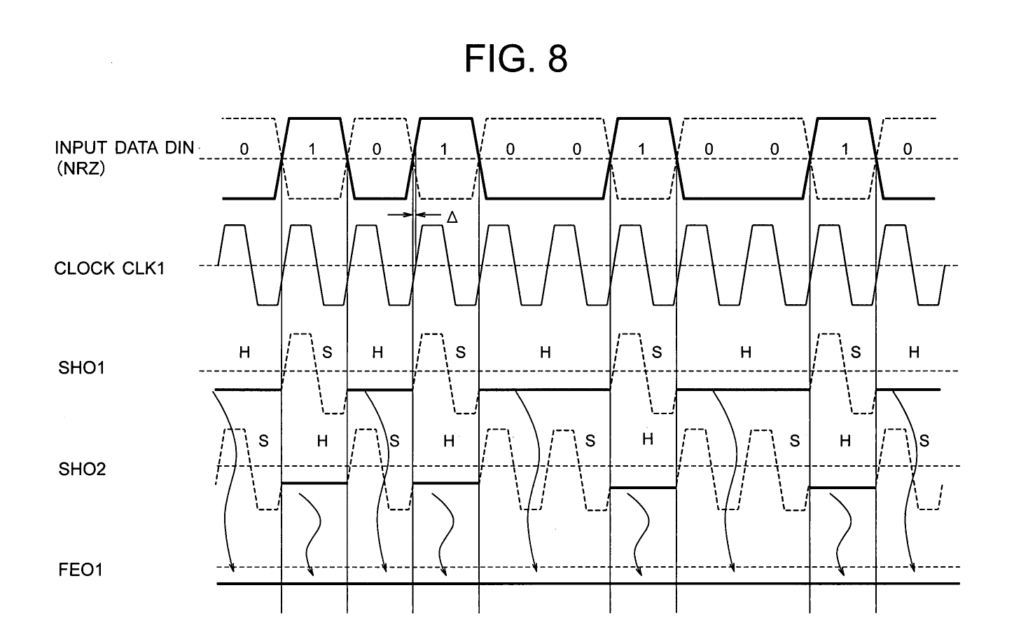

FIG. 9 is a timing chart for indicating operations (half bit rate) of the conventional phase comparator;

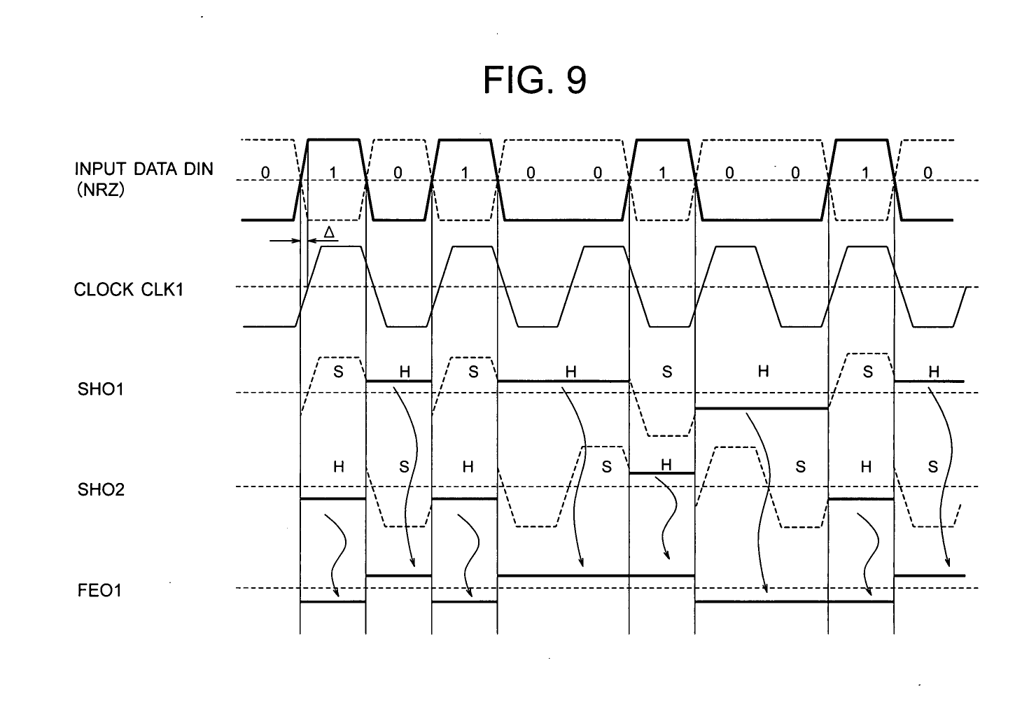

FIG. 10 is a block diagram for showing another arrangement of the conventional phase comparator; and

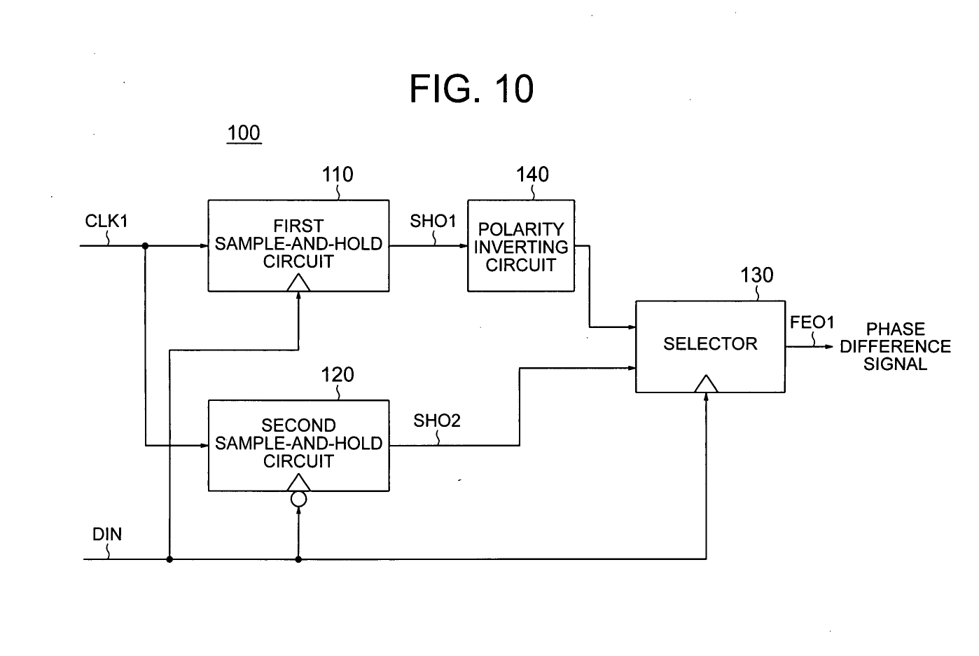

FIG. 11 is a timing chart for indicating operations of the conventional phase comparator shown in FIG. 10.

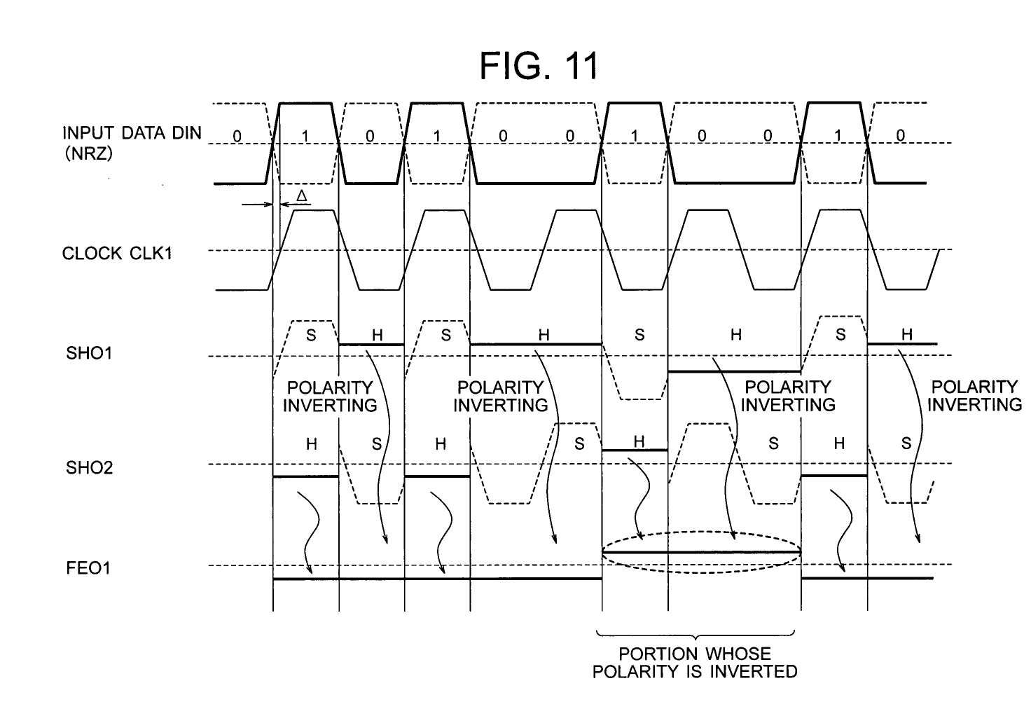

### DETAILED DESCRIPTION OF THE PREFERRED EMBODIMENTS

### First Embodiment

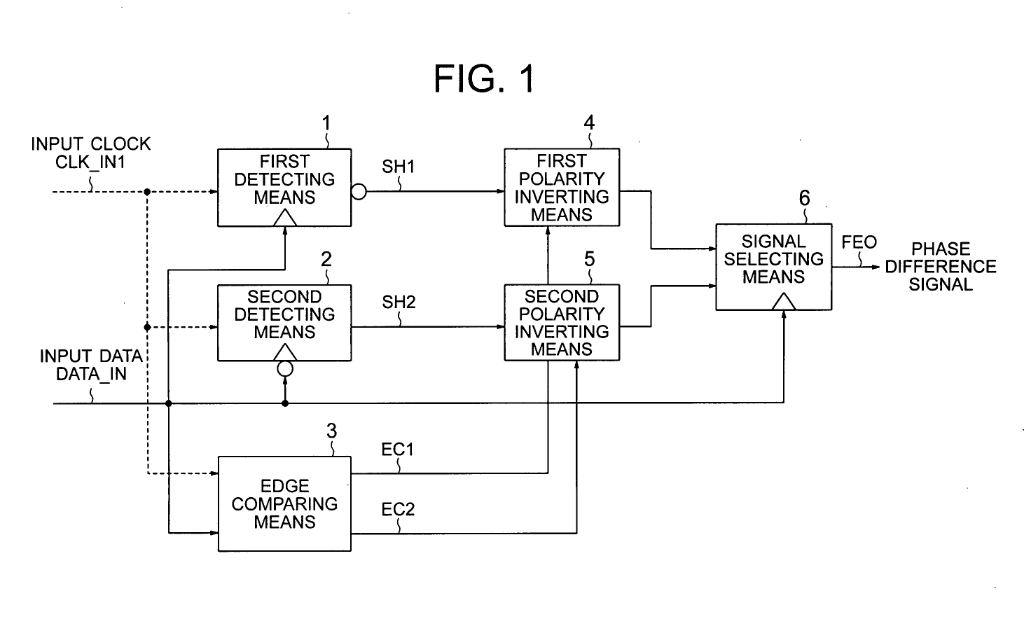

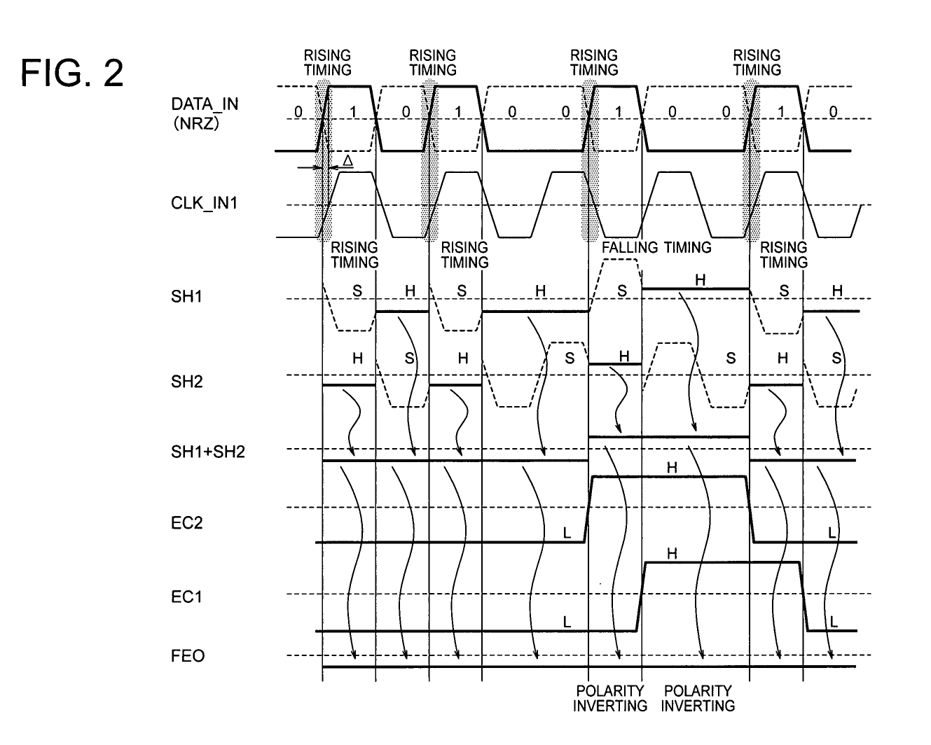

A phase comparator according to a first embodiment of the present invention will now be described with reference to FIGS. 1 and 2. FIG. 1 is a block diagram for showing an arrangement of the phase comparator according to the first embodiment of the present invention. It should be understood that the same reference numerals shown in the respective drawings indicate the same, or equivalent structural portions.

In FIG. 1, the phase comparator, according to the first embodiment, is provided with a first detecting means 1, a second detecting means 2, an edge comparing means 3, a first polarity inverting means 4, a second polarity inverting means 5, and a signal selecting means 6.

The first detecting means 1 starts a sampling operation for an amplitude of an input clock “CLK_IN1” at rising timing of input data “DATA_IN”, and holds an amplitude value of the input clock “CLK_IN1” at falling timing of the input data “DATA_IN” so as to detect the input clock “CLK_IN1”. Then, the first detecting means 1 outputs such a signal that a polarity of the detected value is inverted as an “SH1” to the first polarity inverting means 4.

The second detecting means 2 starts a sampling operation for the amplitude of the input clock “CLK_IN1” at falling timing of the input data “DATA_IN”, and holds the amplitude value of the input clock “CLK_IN1” at rising timing of the input data “DATA_IN” so as to detect the input clock “CLK_IN1”. Then, the second detecting means 2 outputs such a signal as an “SH2” to the second polarity inverting means 5.

Similarly the first detecting means 1 and the second detecting means 2, the edge comparing means 3 employs both the input data DATA_IN and the input clock CLK_IN1. This edge comparing means 3 identifies as to whether the first detecting means 1 detects an amplitude value under a rising state of the input clock CLK_IN1, or an amplitude value under a falling state thereof, and then, outputs an “EC1” corresponding to an identification result to the first polarity inverting means 4. Also, the edge comparing means 3 identifies as to whether the second detecting means 2 detects an amplitude value under a rising state of the input clock CLK_IN1, or an amplitude value under a falling state thereof, and then, outputs an “EC2” corresponding to an identification result to the second polarity inverting means 5.

The signal selecting means 6 selects either an output value of the first polarity inverting means 4 or an output value of the second polarity inverting means 5 in response to a polarity (either “H” or “L”) of the input data DATA_IN to output the selected output value.

Referring subsequently to drawings, a description is made of operations of the phase comparator according to the first embodiment. FIG. 2 is a timing chart for indicating the operations of the phase comparator according to the first embodiment of the present invention. The timing chart shown in FIG. 2 shows such a case that a phase of the input clock CLK_IN is delayed by “Δ”, as compared with a phase of the input data DATA_IN.

The input data DATA_IN is entered in this order of “L”, “H”, “L”, “L”, “H”, “L”, “L”, “H”, “L”, “H” and “L” in the NRZ format, namely, in the order of “0”, “1”, “0”, “0”, “1”, “0”, “0”, “1”, “0”, “1”, and “0” (from right to left).

When the input data DATA_IN is changed from “L” to “H” , the first detecting means 1 starts a sampling operation as to an amplitude value of the input clock CLK_IN1. Also, the second detecting means 2 holds an amplitude value of the input clock CKL_IN1 at rising timing of the input data DATA_IN.

When the input data DATA_IN is changed from “H” to “L”, the first detecting means 1 holds an amplitude value of the input clock CLK_IN1 at falling timing of the input clock CLK_IN1. Also, the second detecting means 2 starts a sampling operation as to the amplitude value of the input clock CLK_IN1.

If a changing point of the input clock CLK_IN1 is under a falling state when the input data DATA_IN is changed from “H” to “L” in the first detecting means 1, then the edge comparing means 3 outputs “L” as the EC1, whereas if a changing point of the input clock CLK_IN1 is under a rising state when the input data DATA_IN is changed from “H” to “L” in the first detecting means 1, then the edge comparing means 3 outputs “H” as the EC1. Then, the edge comparing means 3 holds this output until the input data DATA_IN is subsequently changed from “H” to “L”.

If a changing point of the input clock CLK_IN1 is under a rising state when the input data DATA_IN is changed from “L” to “H” in the second detecting means 2, then the edge comparing means 3 outputs “L” as the EC2, whereas if a changing point of the input clock CLK_IN1 is under a falling state when the input data DATA_IN is changed from “L” to “H” in the second detecting means 2, then the edge comparing means 3 outputs “H” as the EC2. Then, the edge comparing means 3 holds this output until the input data DATA_IN is subsequently changed from “L” to “H”.

If the EC1 is “L”, then the first polarity inverting means 4 does not invert the polarity, whereas if the EC1 is “H”, then the first polarity inverting means 4 inverts the polarity. If the EC2 is “L”, then the second polarity inverting means 5 does not invert the polarity, whereas if the EC2 is “H”, then the second polarity inverting means 5 inverts the polarity. Then, in a time period during which the input data DATA_IN is “H”, the signal selecting means 6 selects an output of the second polarity inverting means 5 to output the selected signal as a phase difference signal “FEO”. Also, in a time period during which the input data DATA_IN is “L”, the signal selecting means 6 selects an output of the first polarity inverting means 4 to output the selected signal as a phase difference signal “FEO”.

As previously explained, in the first embodiment, the edge comparing means 3 identifies as to whether both the first detecting means 1 and the second detecting means 2 detect the amplitude values of the input clocks CLK_IN1 under the rising states, or detect the amplitude values thereof under the falling sates. Then, the edge comparing means 3 determines to invert/non-invert the polarities of the output of the first polarity inverting means 4 and the output of these second polarity inverting means 5 based upon the identification results, so that the polarities of the phase difference signals FEOs can be made matched with each other. Also, by invalidating the operations of the first polarity inverting means 4 and the second polarity inverting means 5, the phase comparator can also be operated in the full bit rate.

### Second Embodiment

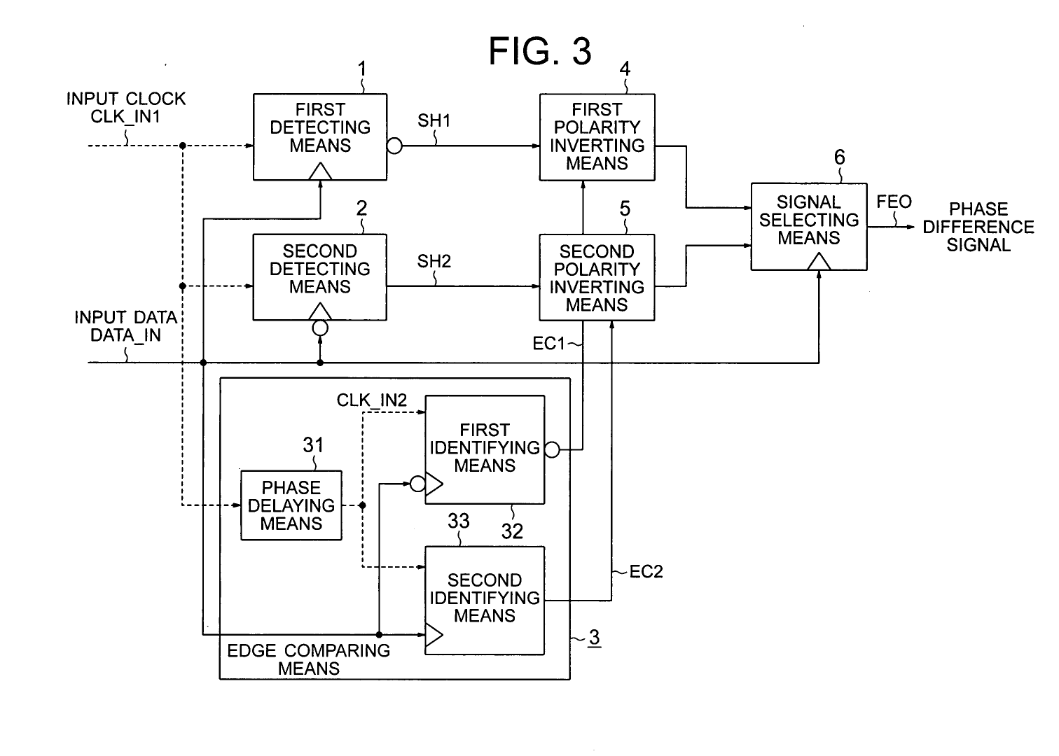

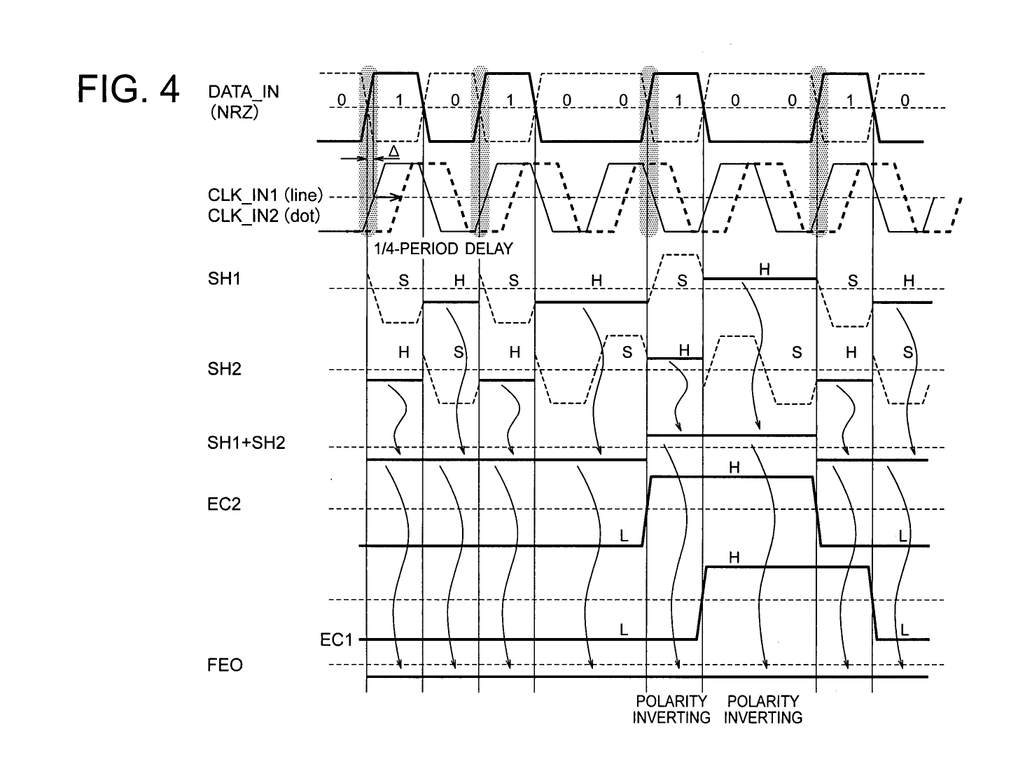

A phase comparator according to a second embodiment of the present invention will now be described with reference to FIGS. 3 and 4. FIG. 3 is a block diagram for showing an arrangement of the phase comparator according to the second embodiment of the present invention.

In FIG. 3, the phase comparator, according to the second embodiment, is provided with the first detecting means 1, the second detecting means 2, the edge comparing means 3, the first polarity inverting means 4, the second polarity inverting means 5, and the signal selecting means 6.

Also, the edge comparing means 3 is constituted by a phase delaying means 31, a first identifying means 32, and a second identifying means 33.

The first detecting means 1 starts a sampling operation for the amplitude of the input clock “CLK_IN1” at rising timing of the input data “DATA_IN”, and holds the amplitude value of the input clock “CLK_IN1” at falling timing of the input data “DATA_IN” so as to detect the input clock “CLK_IN1”. Then, the first detecting means 1 outputs such a signal that a polarity of the detected value is inverted as an “SH1” to the first polarity inverting means 4.

The second detecting means 2 starts a sampling operation for the amplitude of the input clock “CLK_IN1” at falling timing of the input data “DATA_IN”, and holds the amplitude value of the input clock “CLK_IN1” at rising timing of the input data “DATA_IN” so as to detect the input clock “CLK_IN1”. Then, the second detecting means 2 outputs such a signal as an “SH2” to the second polarity inverting means 5.

The phase delaying means 31 delays the phase of the input clock CLK_IN1 by, for example, a ¼ time period, and then, outputs the delayed clock CLK_IN2 to the first identifying means 32 and the second identifying means 33. The first identifying means 32 identifies the delayed clock CLK_IN2 at falling timing of the input data DATA_IN, and then, outputs an inverted signal of this identification result as an “EC1” to the first polarity inverting means 4. The second identifying means 33 identifies the delayed clock CLK_IN2 at rising timing of the input data DATA_IN, and then, outputs this identification result as an “EC2” to the second polarity inverting means 5.

The signal selecting means 6 selects either an output value of the first polarity inverting means 4 or an output value of the second polarity inverting means 5 in response to a polarity (either “H” or “L”) of the input data DATA_IN to output the selected output value.

Referring subsequently to drawings, a description is made of operations of the phase comparator according to the second embodiment. FIG. 4 is a timing chart for indicating the operations of the phase comparator according to the second embodiment of the present invention. The timing chart shown in FIG. 4 shows such a case that a phase of the input clock CLK_IN is delayed by “Δ”, as compared with a phase of the input data DATA_IN.

The input data DATA_IN is entered in this order of “L”, “H”, “L”, “L”, “H”, “L”, “L”, “H”, “L”, “H” and “L” in the NRZ format, namely, in the order of “0”, “1”, “0”, “0”, “1”, “0”, “0”, “1”, “0”, “1”, and “0” (from right to left).

When the input data DATA_IN is changed from “L” to “H”, the first detecting means 1 starts a sampling operation as to an amplitude value of the input clock CLK_IN1. Also, the second detecting means 2 holds an amplitude value of the input clock CKL_IN1 at rising timing of the input data DATA_IN.

When the input data DATA_IN is changed from “H” to “L”, the first detecting means 1 holds an amplitude value of the input clock CLK_IN1 at falling timing of the input clock CLK_IN1. Also, the second detecting means 2 starts a sampling operation as to the amplitude value of the input clock CLK_IN1.

Since the first identifying means 32 which constitutes the edge comparing means 3 identifies the delayed clock CLK_IN2 at the falling timing of the input data DATA_IN and then inverts the identification, the output of the first identifying means 32 becomes “EC1” indicated in FIG. 4. Since a portion of an SH1 whose polarity is wanted to be inverted enters an “H” section of the EC1, the polarities of the SH1 can be matched with each other by inverting the polarities of the SH1 by the first polarity inverting means 4 only in the case that the EC1 is “H”.

Also, since the second identifying means 33 which constitutes the edge comparing means 3 identifies the delayed clock CLK_IN2 at the rising timing of the input data DATA_IN, the output of the second identifying means 33 becomes “EC2” indicated in FIG. 4. Since a portion of an SH2 whose polarity is wanted to be inverted enters an “H” section of the EC2, the polarities of the SH2 can be matched with each other by inverting the polarities of the SH2 by the second polarity inverting means 5 only in the case that the EC2 is “H”.

Then, in a time period during which the input data DATA_IN is “H”, the signal selecting means 6 selects an output signal of the second polarity inverting means 5 to output the selected output signal as a phase difference signal FEO. Also, in a time period during which the input data DATA_IN is “L”, the signal selecting means 6 selects an output signal of the first polarity inverting means 4 to output the selected output signal as the phase difference signal FEO.

As previously explained, in the second embodiment, the edge comparing means 3 produces the delayed clock CLK_IN2 by delaying the input clock CLK_IN1, and identifies this delayed clock CLK_IN2 at both the rising timing and the falling timing of the input data DATA_IN. As a result, the edge comparing means 3 identifies as to whether both the first detecting means 1 and the second detecting means 2 detect the amplitude values under the rising states of the input clocks CLK_IN1, or detect the amplitude values under the falling states thereof. Then, the edge comparing means 3 determines to invert/non-invert the polarities of the output of the first polarity inverting means 4 and the output of the second polarity inverting means 5 based upon the identification results, so that the polarities of the phase difference signals FEOs can be matched with each other.

### Third Embodiment

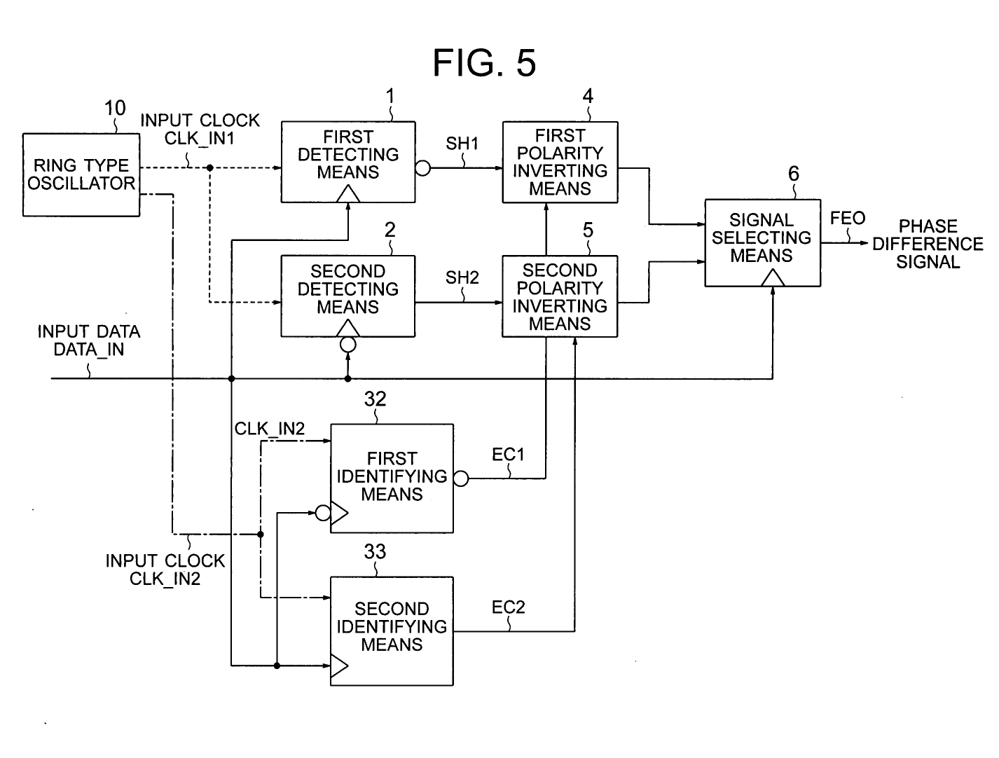

A phase comparator according to a third embodiment of the present invention will now be described with reference to FIG. 5. FIG. 5 is a block diagram for showing an arrangement of the phase comparator according to the third embodiment of the present invention.

In FIG. 5, the phase comparator, according to the third embodiment, is provided with a ring type oscillator 10, a first detecting means 1, a second detecting means 2, a first identifying means 32, a second identifying means 33, a first polarity inverting means 4, a second polarity inverting means 5, and a signal selecting means 6.

Since the ring type oscillator 10 is arranged by employing an even number of amplifiers whose circuit delay amounts are equal to each other, the ring type oscillator 10 can produces a clock CLK_IN1 (first clock signal), and another clock CLK_IN2 (second clock signal) whose phase is delayed by a ¼ time period.

The first detecting means 1 starts a sampling operation for the amplitude of the input clock “CLK_IN1” at rising timing of the input data “DATA_IN”, and holds the amplitude value of the input clock “CLK_IN1” at falling timing of the input data “DATA_IN” so as to detect the input clock “CLK_IN1”. Then, the first detecting means 1 outputs such a signal that a polarity of the detected value is inverted as an “SH1” to the first polarity inverting means 4.

The second detecting means 2 starts a sampling operation for the amplitude of the input clock “CLK_IN1” at falling timing of the input data “DATA_IN”, and holds the amplitude value of the input clock “CLK_IN1” at rising timing of the input data “DATA_IN” so as to detect the input clock “CLK_IN1”. Then, the second detecting means 2 outputs such a signal as an “SH2” to the second polarity inverting means 5.

The first identifying means 32 identifies the ¼-time-period delayed clock CLK_IN2 at falling timing of the input data DATA_IN, and thereafter, inverts the identification result, and then, outputs the inverted identification result as an “EC1” to the first polarity inverting means 4. The second identifying means 33 identifies the ¼-time-period delayed clock CLK_IN2 at rising timing of the input data DATA_IN, and then, outputs the identification result as an “EC2” to the second polarity inverting means 5. The signal selecting means 4 or the output value of the second polarity inverting means 5 in response to the polarity (either “H” or “L”) of the input data DATA_IN to output the selected output value.

As previously explained, in the phase comparator of the third embodiment, the phase delay amount of the delayed clock CLK_IN2 required in the edge comparing means 3 becomes the ¼ time period which is optimized in the first identifying means 32 and the second identifying means 33. It should also be noted that since a timing chart of the third embodiment is identical to that shown in FIG. 4, a description of the timing chart of the third embodiment is omitted.

What is claimed is:

1. A phase comparator, comprising:
a first detecting means for detecting an amplitude value of a clock signal inputted at falling timing of an inputted data signal;
a second detecting means for detecting an amplitude value of the clock signal at rising timing of the data signal;
an edge comparing means for identifying as to whether the first detecting means detects an amplitude value under a rising state of the clock signal or an amplitude value under a falling state of the clock signal to output a first identification result, and for identifying as to whether the second detecting means detects an amplitude value under a rising state of the clock signal or an amplitude value under a falling state of the clock signal to output a second identification result;
a first polarity inverting means for inverting a polarity of an output of the first detecting means in response to the first identification result derived from the edge comparing means;
a second polarity inverting means for inverting a polarity of an output of the second detecting means in response to the second identification result derived from the edge comparing means; and
a signal selecting means for selecting one of an output value of the first polarity inverting means and an output value of the second polarity inverting means in response to a polarity of the data signal to output the selected output value.

2. A phase comparator according to claim 1, wherein the edge comparing means comprises:
a phase delaying means for delaying a phase of the clock signal;
a first identifying means for identifying the delayed clock signal derived from the phase delaying means at the falling timing of the data signal to output the first identification result; and
a second identifying means for identifying the delayed clock signal derived from the phase delaying means at the rising timing of the data signal to output the second identification result.

3. A phase comparator according to claim 2, wherein the phase delaying means delays the phase of the clock signal by a ¼ time period.

4. A phase comparator, comprising:
a ring type oscillator for producing a first clock signal and a second clock signal by delaying a phase of the first clock signal;
a first detecting means for detecting an amplitude value of the first clock signal produced from the ring type oscillator at falling timing of an inputted data signal;
a second detecting means for detecting an amplitude value of the first clock signal produced from the ring type oscillator at rising timing of the inputted data signal;
a first identifying means for identifying the second clock signal produced from the ring type oscillator at the falling timing of the data signal;
a second identifying means for identifying the second clock signal produced from the ring type oscillator at the rising timing of the data signal;
a first polarity inverting means for inverting a polarity of an output of the first detecting means in response to the first identification result derived from the first identifying means;
a second polarity inverting means for inverting a polarity of an output of the second detecting means in response to the second identification result derived from the second identifying means; and
a signal selecting means for selecting one of an output value of the first polarity inverting means and an output value of the second polarity inverting means in response to a polarity of the data signal to output the selected output value.

5. A phase comparator according to claim 4, wherein the ring type oscillator produces both the first clock signal and the second clock signal by delaying a phase of the first clock signal by a ¼ time period.
